(19) United States
(12) Patent Application Publication
(10) Pub. No.: US 2002/0070464 A1
(43) Pub. Date: Jun. 13, 2002

(54) Method for forming a protective package for electronic circuits

(75) Inventor: Giovanni Frezza, Roma (IT)

Correspondence Address: SEED INTELLECTUAL PROPERTY LAW GROUP PLLC, 701 FIFTH AVE, SUITE 6300, SEATTLE, WA, 98104-7092, US

(73) Assignee: STMicroelectronics S.r.I., Agrate Brianza (IT)

(21) Appl. No.: 09/997,995

(22) Filed: Nov. 30, 2001

(30) Foreign Application Priority Data
Nov. 30, 2000 (EP) 00830796.9

(51) Int. Cl. H01L 23/29

(52) U.S. Cl. 257/788

(57) ABSTRACT

A method for forming by molding a plastic protective package for an electronic integrated circuit that includes an electronic device activated from the outside of said protective package. The method includes: dispensing a covering layer of elastic material on a portion of said electronic device; shaping said covering layer to form a projecting portion from a surface of said electronic device; molding said electronic integrated circuit in said plastic protective package using a mold including at least a half-mold abutting against said projecting portion; and obtaining a hole or a window formed in alignment with said projecting portion in said protective package.

### BACKGROUND OF THE INVENTION

1. Field of the Invention

This invention relates to a method for forming a protective package for electronic circuits.

The invention relates, particularly but not exclusively, to a method for forming a plastic protective package for integrated electronic devices, the package being formed with a window so that the contained electronic devices can at least partially be accessed from the outside of the package, and the following description is made with reference to this application field for convenience of illustration only.

2. Description of the Related Art

As it is well known, semiconductor electronic circuits comprising pressure or optical sensors have grown in demand and gained widespread acceptance in recent years.

A prior solution for integrating such electronic devices in a package is shown in FIGS. 1 and 2.

In these figures it is shown, by way of example, a package 1 obtained by a conventional molding technique. This package 1 is substantially tray-like shaped and comprises a support 2 for an integrated circuit.

More particularly, fixed on the support 2 is an integrated circuit comprising a sensor 3, e.g., a proximity or pressure sensor, connected to a control circuitry 4. The circuitry 4 is connected to control pins by thin conductor wires 4a providing as external electrical connection. Both the sensor 3 and the control circuitry 4 are fixed an the support 2 by means of an epoxy adhesive layer 5.

The sensor 3, the circuitry 4 and the support 2 are covered with a coating gel 6.

The package 1 is closed along its edge by a closing element 7 which may be in the form of a window made out of glass, plastic, or another material.

Thus closing element 7 has a hole 8 aligned to the sensor 3. A pivot is slidingly inserted through this hole 8 to activate the sensor 3 from the outside of the package.

Although in many ways advantageous, this prior solution has some drawbacks. To complete the device, it is necessary firstly to form the package, the insert the components into the package, seal the package, and insert the element or operating the sensor through the package window. Also with such devices, the procedure for aligning and positioning the window to insert the element operating the sensor is troublesome, and this makes the device construction difficult to reproduce.

### BRIEF SUMMARY OF THE INVENTION

An embodiment of this invention is directed to a method to form package for electronic circuits comprising a sensor that can be activated from the outside of the package, which method has stable structural and functional features to enable the package being manufactured by conventional molding processes, while overcoming the limitations of the prior art solutions.

Another embodiment of this invention provides a mold and an integrated package comprising sensors that can be activated from the outside of the package.

One of the concepts behind embodiments of this invention is that of forming a package using a conventional molding technique, and provide it with a window aligned to an integrated electronic device, for example a sensor, that is housed inside the package, but in communication with the package exterior. After having fixed the electronic device and control circuit on the support, a surface of the electronic device is covered with a covering layer made out of elastic material so as to form a projecting portion from the device surface. The support is inserted into a mold in such a way that the projecting portion abuts against the superior wall of the mold, when the mold is closed. The mold is then filled with an insulating material to form the package with its window in a single step. Advantageously, the mold has an internally protruding lug aligned with the projecting portion, such that the protruding lug is in pressing contact with the projecting portion, when the mold is closed.

The features and advantages of the method according to the invention will be apparent from the following description of an embodiment thereof, given by way of example and not of limitation with reference to the accompanying drawings.

### BRIEF DESCRIPTION OF THE SEVERAL VIEWS OF THE DRAWINGS

FIG. 1 is an exploded view schematically showing a protective package for integrated circuits according to the prior art;

FIG. 2 shows a perspective view of a protective package for integrated circuits according to the prior art;

FIG. 2a shows a sectional view of a protective package for integrated circuits during the molding process;

FIG. 2b shows a sectional view of an embodiment of a plastic protective package realized with the method according to an embodiment of the invention;

FIG. 3 shows a sectional view of a mold used in molding a protective package for integrated circuits, at the end of the molding processes, according to an embodiment of the invention, FIGS. 4, 5, 6, 7 and 8 are sectional views of embodiments of a plastic protective package at the end of the molding step according to an embodiment of the invention.

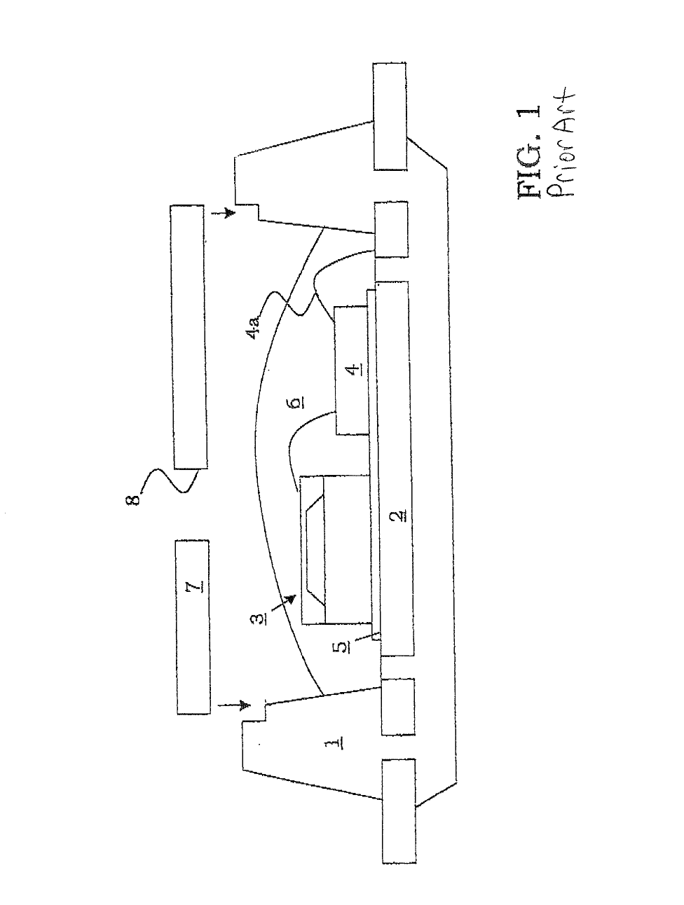

### DETAILED DESCRIPTION OF THE INVENTION

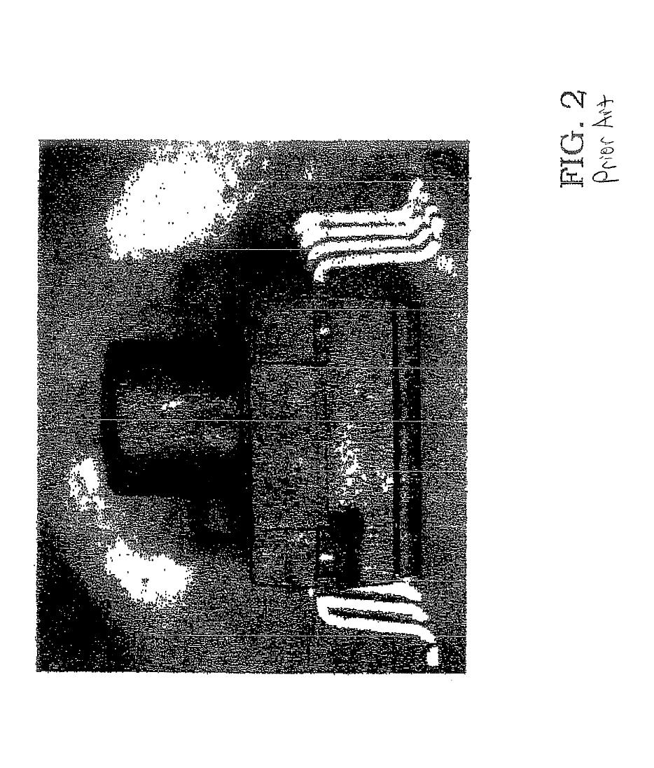

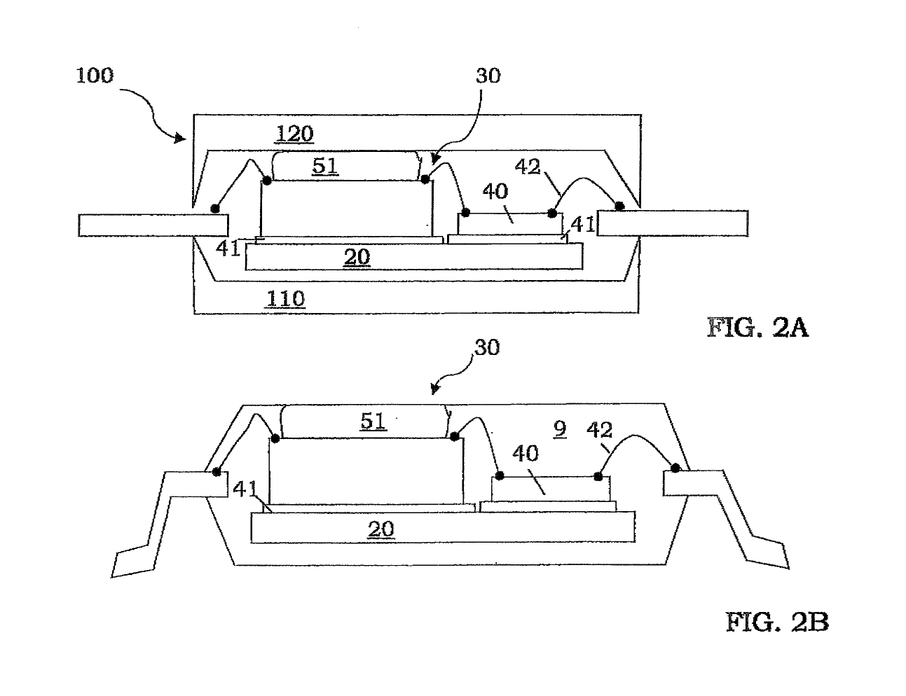

Wilt reference to the drawings, in particular to the examples of FIGS. 2a and 2b a protective package with a window realized with the method according to an embodiment of the invention, is shown.

FIG. 2a shows a vertical section of a single mold 100 delimiting a cavity, although in conventional molding techniques the mold includes a plurality of adjacent dies with mold cavities for simultaneously molding a plurality of packages.

A lead frame or support 20, e.g., in the form of a metal foil, is placed inside the mold cavity, On the lead frame 20 is fixed an electronic circuit comprising an integrated electronic sensor 30, e.g., a proximity sensor of the touch or the optical type. This electronic sensor 30 is fixed to the support 20 by means of a connecting layer 41.

The following description makes reference to these sensor types. Of course, the invention is also applicable to all electronic devices which, although encapsulated within a protective package, should have a surface portion in communication with the package exterior.

According to an embodiment of the invention, a covering layer 50 is provided over the sensor 30. Thus covering layer 50 may consist of a liquid gel, which is subsequently polymerized and made elastic. A suitable material for this layer 50 may be an elastomer or silicon gel.

According to an embodiment of the invention, this covering layer 50 is shaped so to form a projecting portion 51.

Advantageously, a ring is provided on the cap of the sensor 30, which is formed out of semiconductor material, for example. This ring (not shown) is filled with the covering layer 50 material. Thus, the ring will form a barrier or containing dyke for the covering layer 50.

Advantageously, the covering layer 50 creates a protective layer over the surface of the sensor 30 after the protective package is completed.

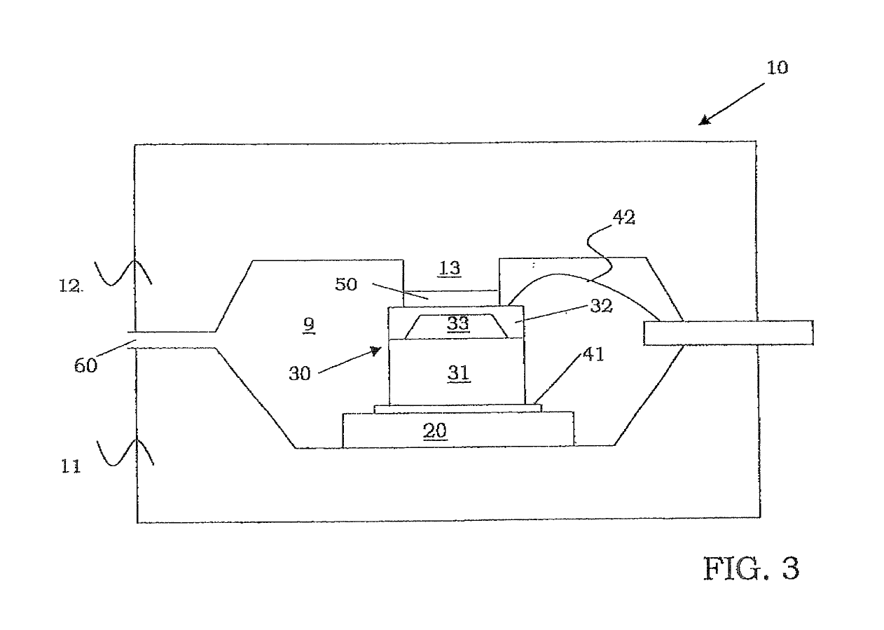

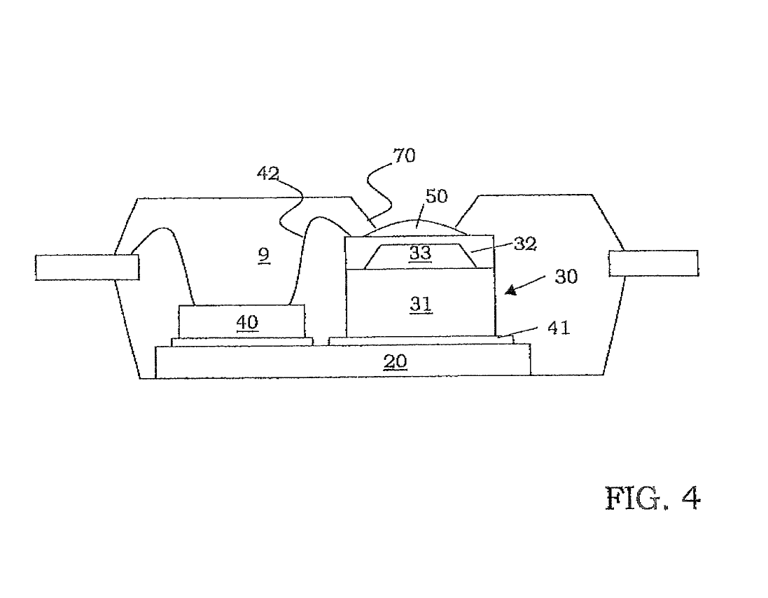

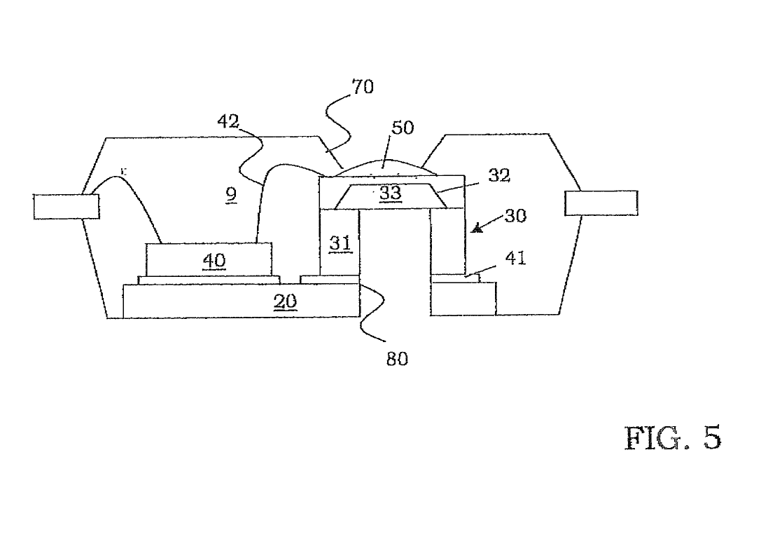

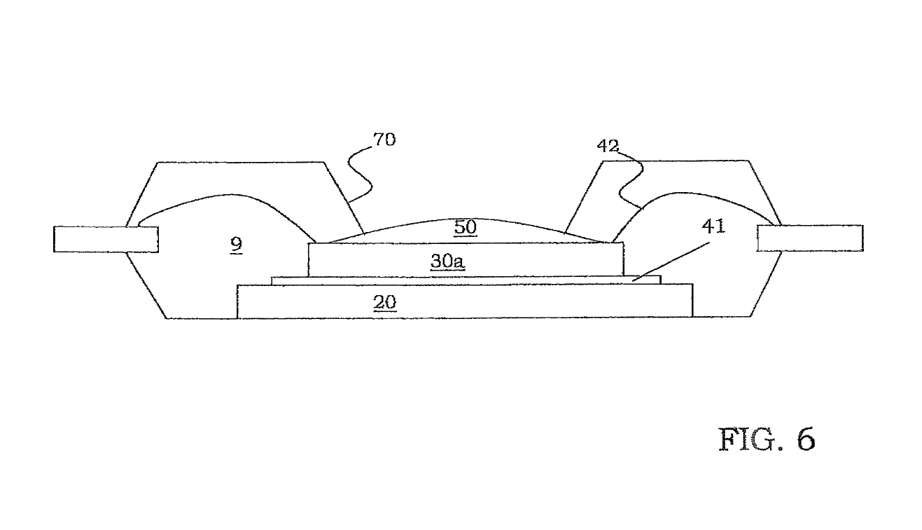

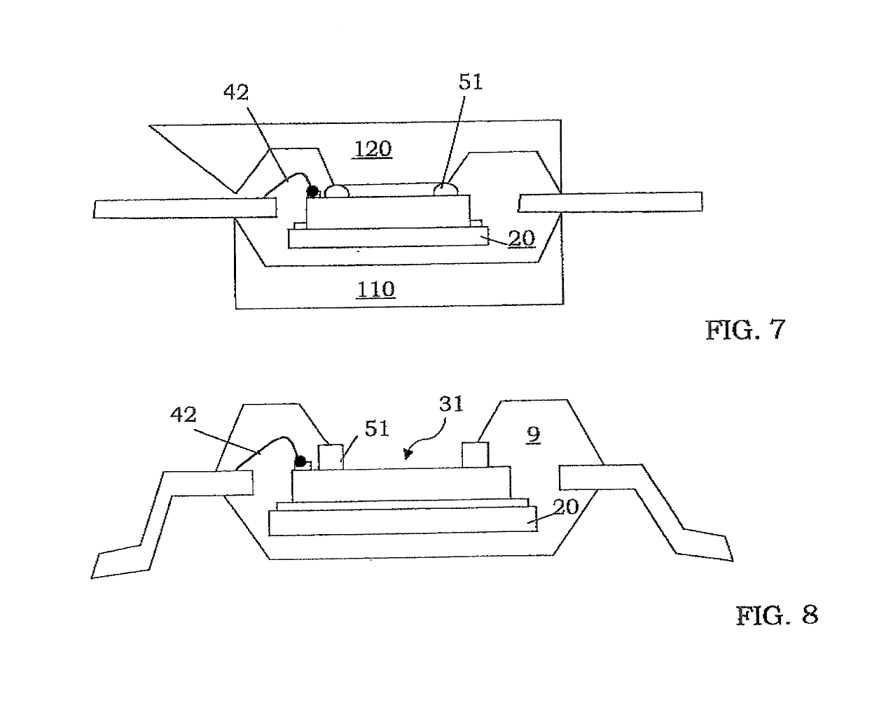

In one embodiment of the invention as shown in FIG. 3, the sensor 30 may comprise a transparent layer 31, e.g., glass, having a membrane 32 of a semiconductor material laid onto it. This membrane 32 has a concavity arranged to face the transparent layer 31 so as to delimit a recess 33.

Advantageously, the membrane 32 has a substantially flat outward surface.

A method of manufacturing the plastic protective package of an embodiment of this invention will now be described.

Shown at 20 in the figures is a metal support, e.g., a heat sink, on which a die formed with an inner integrated circuit is mounted.

The integrated circuit comprises a sensor 30 which can be activated from the outside of a protective package 9 and is connected to a control circuitry 40. The circuitry 40 is connected to pins by thin conductor wires 42 providing an external electrical connection.

Advantageously, the support 20 is located on the bottom of the mold cavity of a conventional mold 100, specifically inside the recess formed by the lower half-mold 110.

According to an embodiment of the invention, the surface of the sensor 30 is at least partially coated with a covering layer 50, e.g., a gel comprising an elastomer, or a silicon gel.

This is followed by well-known thermodynamic processes for cooling and curing the resin.

As a result of the projecting portion 51 abutting against the upper wall of the upper half-mold 120, the package 10 will ultimately show a hole or a window 70 at the location of the sensor 30.

In FIG. 3, an advantageous embodiment is shown. A mold 10 essentially comprises two parts: a lower half-mold 11 and an upper half-mold 12. When the two half-molds are clamped together, a space or mold cavity is defined for containing the electronic circuit.

According to this embodiment, the upper half-mold 12 has an internal protruding lug 13 centrally projecting therein, approximately at the location of the sensor 30. This lug 13 is positioned such that, when the half-mold 12 sand the lower half-mold 11 are superimposed, the lug 13 will abut against, or at least touch, the sensor covering layer 50.

Advantageously, the lug 13 is substantially shaped cylinder and has the same width as the covering layer 50.

In an alternative embodiment, the lug 13 may be substantially shaped as a truncated conic.

Advantageously, the bottom surface of the lug 13 has a smaller area than the top surface of the sensor, and consequently of the projected portion 51.

So when the upper half-mold 12 is clamped with the lower half-mold 11, the lug 13 is placed such that it is abutted against the projecting portion 51.

Where the lug 13 is shaped as a truncated cone, the window 70 will show with tapering walls toward the sensor 30.

In this embodiment it is only necessary that Ube projecting portion 51 abuts against the lug 13, so that the formation of the projecting portion 51 is less critical.

Shown in FIG. 5 is a package 9 which has been molded according to an embodiment of the invention in the instance of a pressure sensor 30 being integrated therein.

In this case, both the support 20 and the glass layer 31 of the sensor 30 are formed with a hole 80 that opens into the recess 33 under the membrane 32.

Particularly, this covering layer 50 is shaped so to form a projecting portion 51 from the sensor 30.

The formation of such projecting portion 51 is realized by volumetric dispensation on the sensors before that the single device are divided by the wafer or during the mounting step of the circuit.

Alternatively, this projecting portion 51 is formed by a technique known as screen printing that provides a precise shaping of the projecting portion 51.

Advantageously, a dyke, e.g., ring-shaped, is formed on the top surface of the sensor 30. The covering layer 50 is then deposited inside this barrier provided by the dyke, the projecting portion 51 so formed being surrounded by the dyke indeed.

The support 20 is placed into the cavity of the conventional mold 100, and precisely inside the recess of the lower half-mold 110, with the sensor 30 mounted thereon. The pins are laid onto the half-molds 110 outside of the recess.

The upper half-mold 120 is then clamped down onto the lower half-mold 110, so that a containing space is created between the two half-molds 110 and 120 as shown in FIG. 2a.

When the upper half-mold 120 is clamped onto the lower half-mold 110, the projecting portion 51 abuts against the upper wall of the mold cavity of the closed mold.

According to an embodiment of the invention, the projecting portion 51 protects the sensor 30 from potential damage by the pressure of the upper half-mold 120 against the surface of the sensor 30 when the half-mold 120 is clamped down onto the lower half-mold 110. In fact, the projecting portion 51 provides a cushioning effect.

In particular, with the projecting portion 51 made out of an elastic material, as the upper half-mold 120 is clamped down onto the lower half-mold 110, the projecting portion 51 cedes to the pressure from half-mold 120 and prevents cracking of the sensor surface.

Once the two half-molds 110 and 120 are clamped together, the step of forming the protective package 9 is carried out.

A plastic material, such as an epoxy resin, is pressure injected, inn a molten state at a high temperature, into the mold cavity between the half-molds 110 and 120 through an inlet 60 and runners (not shown).

Here again, a package 9 having a window 70 aligned to the sensor 30 can be obtained using a conventional mold 100 and forming the projecting portion 51 from the sensor 30 or using a mold 10 with a lug 13.

The mold and the method of this invention can also advantageously be used with an integrated circuit provided with optical sensors, as shown in FIG. 6.

In this embodiment, an optical sensor 30a is fixed on the support 20. The sensor 30a is coated with a covering layer 50 before the molding steps to build the protective package 9 according to an embodiment of the invention

In this embodiment, the covering dyer 50 is transparent to UV radiation.

In all above described embodiments, the covering layer 50 may be removed from the surface of the sensor 30 after the package 9 is formed.

In FIGS. 7 and 8, it is shown another embodiment of the invention. In particular, the projection portion 51 is shaped as a ring. Also in this case, when the upper half-mold 120 clamped onto the lower half-mold 110, the ring shaped projecting portion 51 abuts against the upper wall of the mold cavity of the closed mold.

Once the two half-molds 110 and 120 are clamped together, the plastic material is pressure injected, in a molten state at a high temperature, into the mold cavity between the half-molds 110 and 120 through the inlet 60.

In this embodiment the ring shaped projecting portion 51, abutting against the upper wall of the mold cavity during the molding step, prevents that the plastic material covers the inner part 31 of the sensor 30 surrounded by this ring shaped projecting portion 51. So the formed package 9 is provided with a windows in which a portion of surface of the sensor is free from both the plastic material and the covering layer 50.

In FIG. 7, the package 9 is formed with a mold provided with the lug 14. However, this embodiment can be realized also with a conventional mold.

To conclude, the method and the mold according to an embodiment of the invention allow a plastic protective package, integrated with a sensor that can be activated from the outside of the package, to be manufactured by a conventional molding technique.

Electronic devices package obtained by means of the mold according to an embodiment of the invention allow a more precise manufacturing processes, since all the steps of aligning the window 70 are carried out during the molding step, Thus, a better reproducibility of a window aligned with the device is therefore ensured.

Changes can be made to the invention in light of the above detailed description. In general, in the following claims, the terms used should not be construed to limit the invention to the specific embodiments disclosed in the specification and the claims, but should be construed to include all methods and devices that are in accordance with the claims. Accordingly, the invention is not limited by the disclosure, but instead its scope is to be determined by the following claims.

1. A method for forming by molding a plastic protective package for an electronic integrated circuit comprising an electronic device activated from the outside of said protective package, the method comprising the following steps:
dispensing a covering layer of elastic material on a portion of said electronic device;
shaping said covering layer to form a projecting portion from a surface of said electronic device;
molding said electronic integrated circuit in said plastic protective package using a mold including at least a half-mold abutting against said projecting portion;
obtaining a hole or a window formed in alignment with said projecting portion in said protective package.

2. The method according to claim 1 wherein said covering layer is formed by elastic material.

3. The method according to claim 2 wherein said projecting portion is realized by volumetric dispensing of said elastic material.

4. The method according to claim 2 wherein said elastic material is a silicon gel.

5. The method according to claim 2 wherein said projecting portion is realized by screen printing of said elastic material.

6. The method according to claim 5 wherein said elastic material is a silicon gel.

7. The method according to claim 1 wherein said projecting portion is shaped as a ring.

8. The method according to claim 1, comprising a further step of forming a dyke or barrier on the electronic device to surround said projecting portion.

9. The method according to claim 8 wherein said dyke or barrier is formed before said covering layer on the electronic device.

10. The method according to claim 1 wherein that said half-mold has a lug protruding inside the mold and abutting against said projecting portion during the molding step.

11. The method according to claim 1 wherein that said covering layer is removed after the molding step.

12. A mold for molding a plastic protective package encapsulating an integrated electronic circuit that includes an electronic device, the mold comprising a pair of superimposed half-molds defining a mold cavity for containing said integrated circuit, wherein one half-mold has a lug protruding substantially at a location of said electronic device and abutting against the electronic device during a molding step.

13. The mold for molding a plastic protective package according to claim 12 wherein a covering layer is interposed between said lug and said electronic device during the molding step.

14. The mold for molding a plastic protective package according to claim 13 wherein said covering layer is shaped to form a projecting portion from said electronic device.

15. The mold for molding a plastic protective package according to claim 12 wherein said projecting portion is shaped to form a ring.

16. The mold for molding a plastic protective package according to claim 13 wherein said covering layer covers the integrated device.

17. The mold for molding a plastic protective package according to claim 12 wherein said lug is cylindrical in shape.

18. The mold for molding a plastic protective package according to claim 12 wherein said lug is truncated conical in shape.

19. A plastic protective package for a semiconductor-integrated electronic circuit, comprising a support for an electronic device that can be at least partially activated from the outside of said protective package; wherein said protective package is provided with a hole or a window aligned to at least one portion of said integrated device that is at least partially filled by a projecting portion of elastic material projecting from a surface of the electronic device.

20. The plastic protective package according to claim 19 wherein said projecting portion is shaped to form a ring on the integrate device.

21. The plastic protective package according to claim 19 wherein said hole has tapering walls toward said electronic circuit.

22. The plastic protective package according to claim 19 wherein said projecting portion is surrounded by dyke or barrier formed on the surface of the electronic device.

23. The plastic protective package according to claim 19 wherein said projecting portion is surrounded by dyke or barrier formed around the electronic device.
